(19) United States
(12) Patent Application Publication
(10) Pub. No.: US 2018/0188460 A1
(43) Pub. Date: Jul. 5, 2018

(54) Light Generating Apparatus

(71) Applicant: Versalume LLC, Santa Clara, CA (US)

(72) Inventors: Mario PANICCIA, Santa Clara, CA (US); Qing TAN, Santa Clara, CA (US); Kevin G. SULLIVAN, Freemont, CA (US)

(21) Appl. No.: 15/863,175

(22) Filed: Jan. 5, 2018

Related U.S. Application Data
(60) Provisional application No. 62/442,551, filed on Jan. 5, 2017.

(51) Int. Cl. G02B 6/42; H01S 5/022; H01S 5/024; H01S 5/042; G02B 6/38

(52) U.S. Cl. CPC G02B 6/4267; H01S 5/02212; H01S 5/02284; H01S 5/02469; H01S 5/02248; G02B 6/428; H01S 5/042; G02B 6/4292; G02B 6/3825; G02B 6/4269; G02B 6/4263

(57) ABSTRACT

A light generating apparatus that is capable of being coupled to a connector that supports the proximal end of a light diffusing fiber. According to one implementation the light generating apparatus includes a laser having a housing and a focus lens through which light generated by the laser is emitted. The apparatus also includes a heat removing metallic receptacle that has a first end that is thermally connected to the laser housing and a second end that is connectable to the light diffusing fiber connector. The metallic receptacle has an internal cavity that provides a direct line of sight between the focus lens of the laser and the proximal end of the light diffusing fiber when the connector is coupled to the second end of the metallic receptacle.

### CROSS REFERENCE TO RELATED APPLICATIONS

This application claims priority under 35 U.S.C. § 119(e) from U.S. Provisional Patent Application Ser. No. 62/442,551, filed Jan. 5, 2017, the entire contents of which are hereby incorporated by reference.

### FIELD

The present disclosure relates to an apparatus for generating a beam of light.

### BACKGROUND

Lasers are generally compact in size and designed to emit a monochromatic and convergent light output. The wavelength of light emitted by a laser determines its color. For example, red light has a wavelength of between about 630-750 nanometers, green light has a wavelength of between about 510-530 nanometers, and blue light has a wavelength of between about 440-460 nanometers. The operating voltage of lasers that emit these colors varies from about 3 volts to 8 volts. And because the power conversion efficiency of a laser is very low (about 8-10%), a significant amount of heat is produced in the laser, particularly in relationship to its compact design. Overheating of a laser beyond its maximum operating temperature can adversely impact the wavelength of the emitted light and can also accelerate the degradation of the parts that form it.

Corning Inc., has developed an optical fiber that is capable of diffusing light along its length. Examples of such light diffusing fibers are disclosed in U.S. Pat. No. 8,591,087 which is incorporated by reference in its entirety herein. The light diffusing fiber comprises a core and cladding and is configured to scatter guided light via nano-sized structures located within the core or at a core-cladding boundary. The light diffusing fiber has a diameter (core+cladding) of about 300 μm, and according to at least some implementations, emits substantially uniform radiation over its length and has a scattering-induced attenuation greater than 50 dB/km for light wavelengths within the 200 nm to 2000 nm range.

### SUMMARY

According to the various exemplary implementations disclosed herein, solutions are provided to protect a laser from overheating beyond its maximum operating temperature while at the same time providing a solution for operatively coupling an optical fiber with the laser. Solutions are also provided in the form of controllers that effectively determine the type of light to be emitted by the laser. According to some implementations the type of light emitted by the laser is indicative of a measured parameter such as, for example, sound, ambient light, temperature, humidity, altitude, speed, acceleration, pressure, GPS coordinates, etc.

### BRIEF DESCRIPTION OF THE DRAWINGS

FIG. 1 is an exploded view of a light generating apparatus according to one implementation;

FIG. 2 is a cross-sectional side view of the light generating apparatus in an assembled state;

FIG. 3 is a perspective view of an optical fiber having an LC connector attached to an end thereof;

FIGS. 4A and 4B show a perspective view of a heat removing metallic receptacle according to one implementation;

FIG. 5A is a front view of an exemplary laser that may be used in the light generating apparatus of FIG. 1.

FIG. 5B is a side view of the laser depicted in FIG. 5A;

FIG. 6A is a perspective view of the light generating apparatus depicted in FIG. 1

FIG. 6B is a front view of the light generating apparatus depicted in FIG. 6A;

FIG. 7 is a block diagram of a main control board, laser board and laser according to one implementation;

FIG. 8 is a basic block diagram of a main control board of a light generating apparatus according to one implementation.

FIG. 9 is a screen shot of an exemplary touch screen display which a user may use to control the light generating apparatus through an IOS application running on a smartphone;

FIG. 10 is a cross-sectional side view of USB light generating module according to one implementation;

FIG. 11 is a perspective view of the USB light generating module depicted in FIG. 10;

FIG. 12 is a screen shot of an exemplary touch screen display which a user may use to control the USB light generating module through an IOS application running on a smartphone;

FIG. 13A is an exploded view of a wearable light generating module according to one implementation;

FIG. 13B is a top view of the wearable light generating module depicted in FIG. 13A.

### DETAILED DESCRIPTION

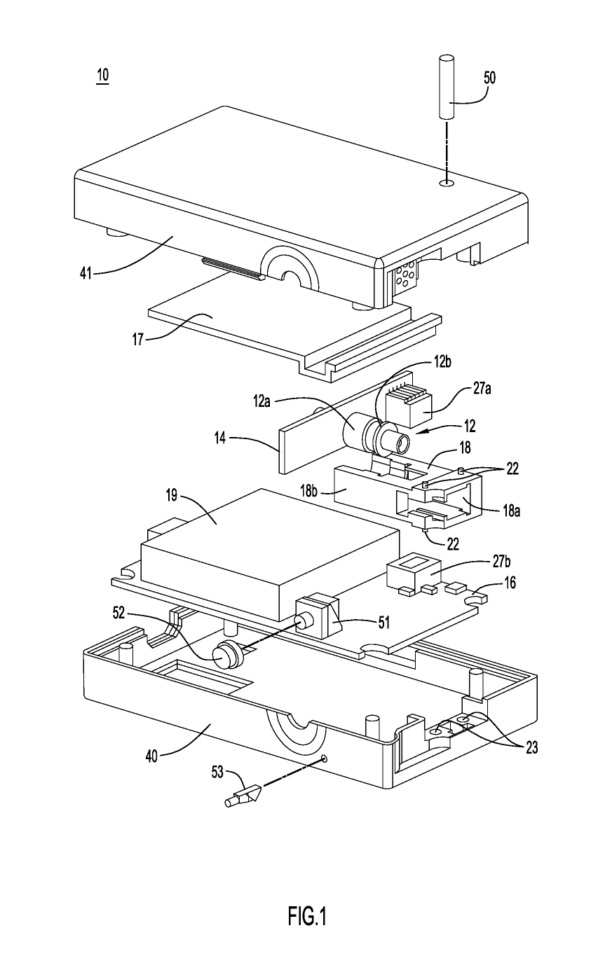

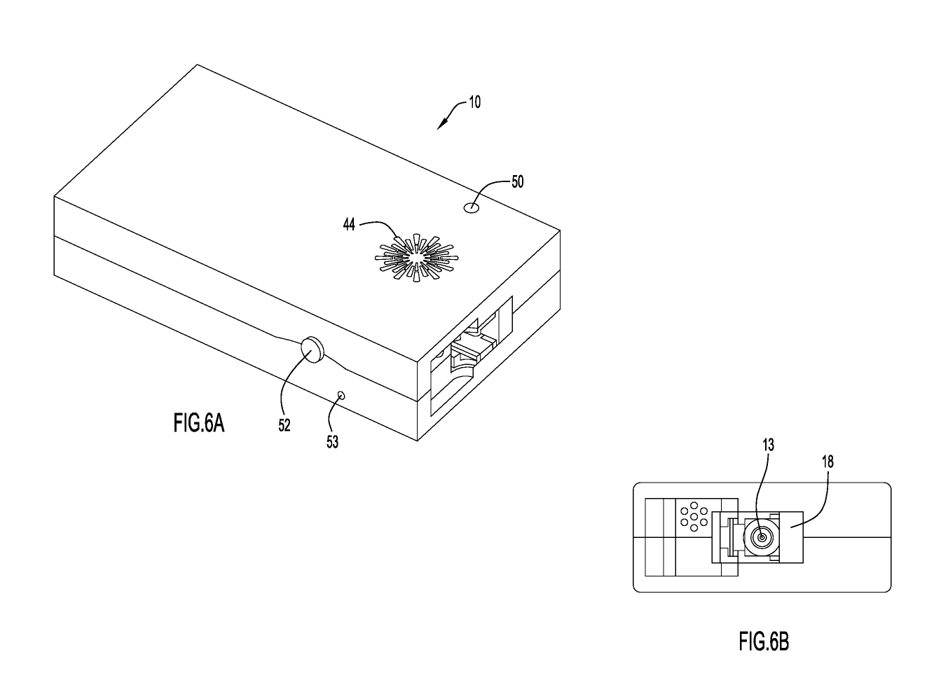

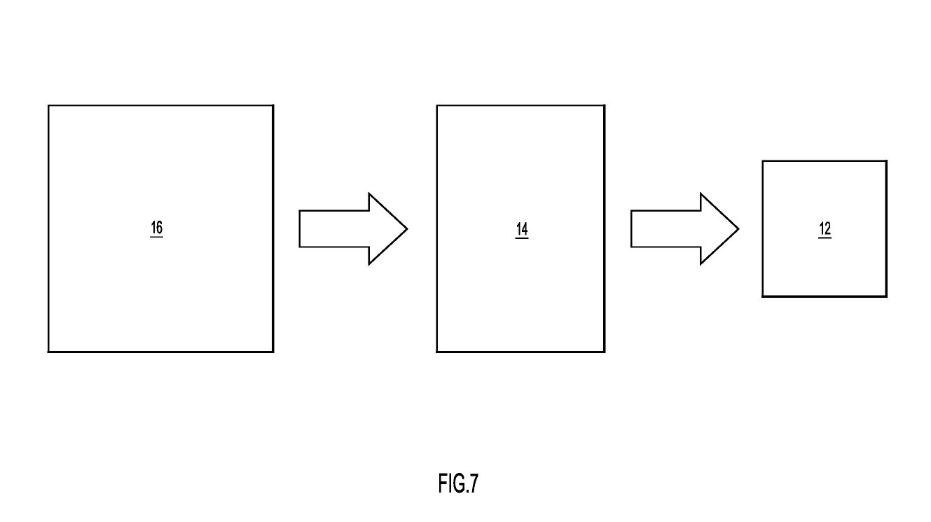

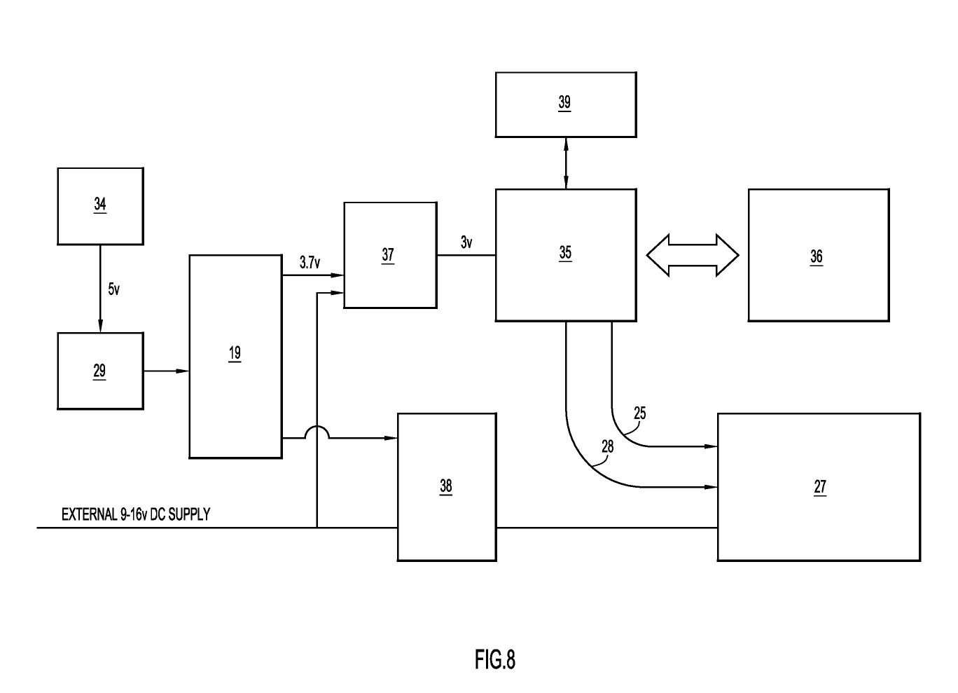

FIG. 1 shows an exploded view of a light generating apparatus 10 according to one implementation. Because the light generating apparatus comprises intelligence for controlling the type of light emitted therefrom, it will be referred to herein as a “smart module”. FIG. 6A is a perspective view of a light generating apparatus in a final assembled state. FIG. 6B is a front view of the light generating apparatus depicted in FIG. 6A.

The smart module includes a laser 12 that is connected to a driver in the form of an integrated circuit located on a printed circuit board 14 (hereinafter referred to as a “laser board”) onto which the laser 12 is mounted. The driver is configured to produce an operating current output to the laser 12 in a manner consistent with signals received from a main control board 16. The working details of the main control board 16 and the laser board 12 are discussed in more detail below.

According to some implementations the laser comprises a laser diode such as the Green Laser Diode in TO38 ICut Package™ and Blue Laser Diode in TO38 ICut Package™ manufactured by OSRAM Opto Semiconductors. FIG. 5A shows a front view of an exemplary laser that includes a focus lens 13 that directs light out the distal end of the laser package. FIG. 5B illustrates an exemplary side profile of a laser.

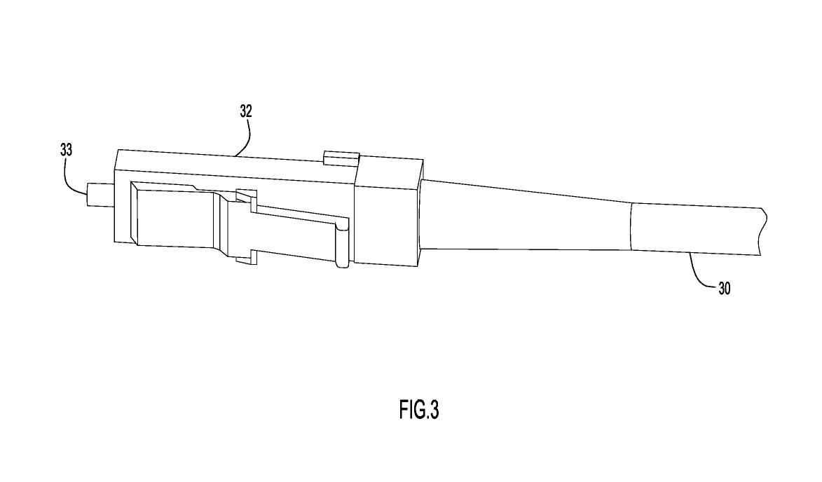

The light output of the laser 12 is deliverable to an optical fiber 30 via a fiber optic connector 32, such as an LC connector depicted in FIG. 3. The optical fiber 30 may be, for example, a light diffusing fiber described above. When, for example, an LC connector is used, a facing proximal end of the optical fiber is located in a proximal positioned ferrule 33 that has an open end that is capable of being optically aligned with the focus lens 13 of the laser 12.

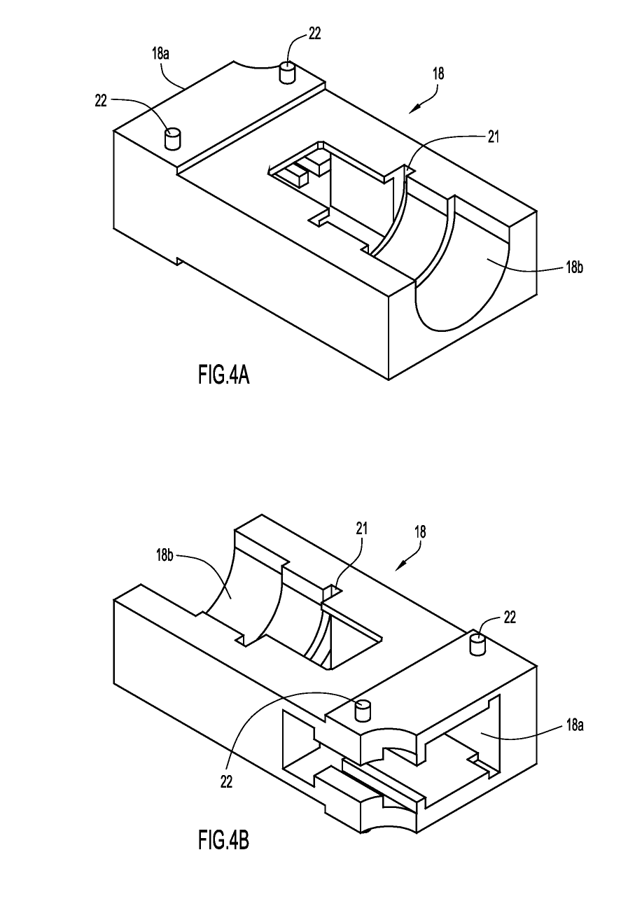

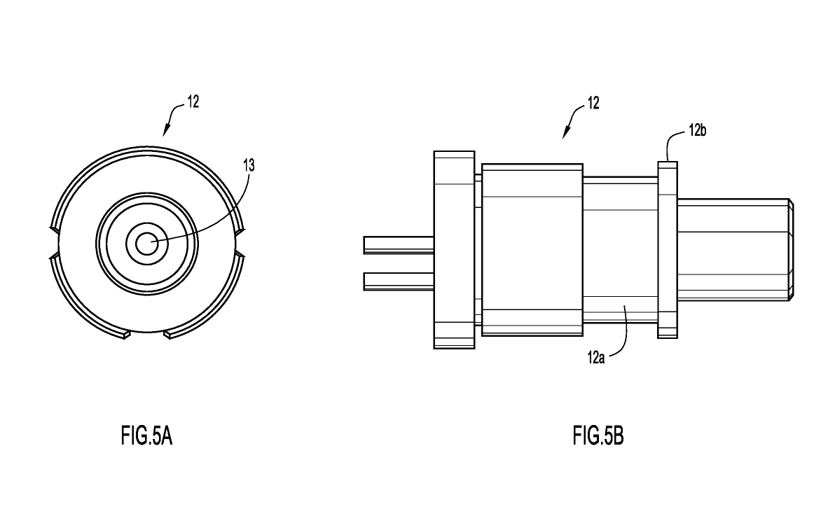

As discussed above, it is important that the operating temperature of the laser 12 be maintained below a maximum operating temperature that is set by the manufacturer of the device. In accordance with one aspect of the present disclosure a high thermal conductive metallic receptacle 18 (see FIGS. 1 and 4) is interposed between the fiber optic connector 32 and the laser 12. A distal end 18a of the receptacle 18 is configured to receive and support the fiber optic connector 32 in a manner that enables the fiber optic connector to be easily locked inside the receptacle and, when desired, subsequently easily removed from the receptacle. An inner cavity of the receptacle 18 provides a direct line of sight between the focus lens 13 of the laser 12 and the proximal end of the light diffusing fiber 30 when the fiber optic connector 32 is coupled to the distal end of the receptacle.

A proximal end 18b of the receptacle 18 is structured to make intimate contact with at least a portion of the laser housing 12a to provide a thermal conductive path for heat to flow out and away from the laser 12. According to some implementations, as shown in FIGS. 1 and 5, the outer profile of the laser housing 12a is curved (e.g. circular, semi-circular, etc.) and the proximal end 18b of the receptacle 18 comprises a complementary mating surface that intimately contacts the curved outer surface of the laser housing. It is important to note, however, that the laser housing 12 and the complementary mating surface of the receptacle need not be curved.

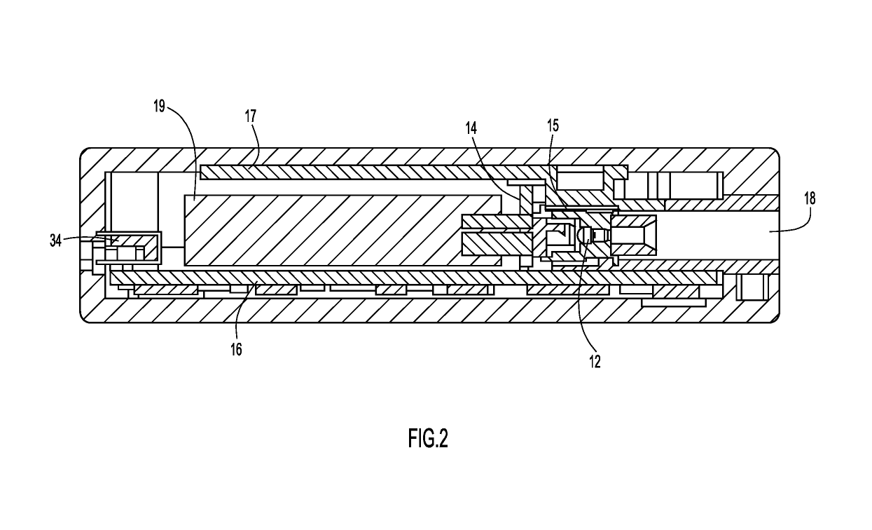

According to some implementations a thermal grease resides at the interface of the laser housing 12a and the complementary mating surface of the receptacle 18 to enhance heat transfer between them. Further, as shown in FIGS. 1 and 2, the receptacle 18 is thermally connected to a heat spreader 17 that has an exposed surface area much greater than that of the receptacle 18. The heat spreader 17 may comprise any of a variety of heat conducting materials. According to one implementation the heat spreader is made of aluminum.

As shown in FIG. 2, according to some implementations a thermal grease 15 is also disposed between the receptacle 18 and the heat spreader 17 to enhance heat transfer between them. Further, as shown in FIG. 6A, according to some implementation the lid 41 of the smart module housing comprises a plurality of through openings 44 through which heat generated inside the smart module may be expelled.

With reference to FIGS. 1. 5A and 5B, according to some implementations in order to maintain the laser 12 and receptacle 18 in proper alignment the outer housing 12a of the laser 12 includes a lip 12b that resides inside a groove 21 located in the receptacle 18.

According to some implementations the distal end 18a of the receptacle 18 has one or more male parts 22 protruding therefrom. In the implementation of FIGS. 1 and 4, the receptacle 18 includes two male parts protruding from each of its top and bottom surfaces. In turn, the base 40 and lid 41 of the smart module housing each include two complementary female parts 23 in which the male parts 22 of the receptacle reside when the smart module is in the assembled state. This construction in conjunction with the alignment provision discussed in the previous paragraph ensures that when the smart module is assembled the receptacle 18 is positioned to provide a proper line of sight between the laser focus lens 13 and the proximal end of the optical fiber disposed in the fiber optic connector 32. It is appreciated that fewer or more male and female parts may be used to accomplish the same objective. It is also appreciated that the smart module housing components may comprise the one or more male parts and the receptacle 18 may comprise the one or more female parts.

According to some implementations, the receptacle 18 is easily removable from the smart module housing, with there being no use of an adhesive to fixate the receptacle to the housing. According to some implementations the male parts are press-fit inside the female parts. As will be discussed in more detail below, the removability of the receptacle enables the laser board 14 and the laser 12 attached to it to be easily replaced in the event the laser becomes damaged or is desired to be replaced with another type of laser (e.g. replacing a blue light emitting laser with a green light emitting laser). As will be discussed in more detail below, this also simplifies the manufacturing of the smart module 10. The receptacle 18 may, however, be fixed to the smart module housing by use of an adhesive.

The metallic receptacle may be made from any of a number of materials including, but not limited to, aluminum, copper, brass, zinc, etc., and according to some implementations has a heat transfer coefficient of at least greater than 100 W/m·K. According to some implementations the material is capable of being stamped to form the receptacle structure. Zinc oxide is an example of such a material.

According to the various exemplary implementations disclosed herein, solutions are provided to protect a laser from overheating beyond its maximum operating temperature while at the same time providing a solution for operatively coupling an optical fiber with the laser.

As evidenced by the aforesaid disclosure, the metallic receptacle 18 provides a solution for conducting heat away from the laser 12 while at the same time providing a solution for operatively coupling the light diffusing optical fiber 30 with the laser 12. The multi-functionality of the receptacle 18 advantageously reduces the number of parts in the construction of the smart module. This beneficially results in reduced manufacturing costs and enables the smart module to assume a more compact design.

As shown in FIG. 7, according to some implementations the smart module 10 includes three major components. These are the main control board 16, the laser board 14 and the laser 12. According to some implementations the laser 12 is hardwired to the laser board 14, and the laser board is removably coupled to the main control board 16 by use of a socket type connector, such as, for example, a Molex 10 pin connector 27. As shown in FIG. 1, the connector may comprise a female part 27a coupled to the laser board 14 and a male part 27b that is coupled to the main control board 16. As with the implementation above where the receptacle is removably attached to the laser housing 12a, the ability to easily remove the laser board 14 from the control module 10 allows the laser 12 to be easily replaced in the event the laser becomes damaged or is desired to be replaced with another type of laser (e.g. replacing a blue light emitting laser with a green light emitting laser).

According to some implementations the smart module 10 utilizes not a single laser but multiple lasers such as those found in an RGB module.

Power is delivered to a driver circuit located on the laser board 14 from the main control board 16 at a given voltage. As explained earlier, each type of laser (e.g. red, blue and green) operates at given rated voltage that in the example of red, blue and green lasers ranges between about 3 DC volts to about DC 8 volts. For example, a red laser typically requires a 3-5 DC volt power source, a blue laser typically requires a 5.2-6.5 DC volt power source and a green laser typically requires a DC 6.5-8.0 volt power source.

As shown in FIG. 8, the smart module 10 power source may be a rechargeable battery 19 and/or an external power source. The external power source may come from a conventional 110 volt source or from a system into which the control module is embedded. The system may be that of an automobile, airplane, etc.

According to some implementations, in order to use a common main control board 16 with a plurality of different lasers, the main control board 16 is configured to deliver an output voltage that is high enough to support all of the laser boards that are contemplated to be used with the main control board. For example, in situations where it is contemplated that the main control board 16 will be used to control red, blue and green lasers, the output voltage of the main control board is set to be equal to or greater than 8.0 volts. The driver circuit on the laser board 14 is configured to step down the voltage according to the requirements of the respective lasers. This feature, in conjunction with the ability to switch out one laser from another as described above, greatly simplifies the manufacturing and assembly of the smart module 10, thereby reducing costs.

FIG. 8 is a basic block diagram of a main control board according to one implementation. The board comprises a printed circuit board on which a variety of components are attached, configured and electrically interconnected to produce one or more output pulse width modulation signals 25. A single pulse width modulation signal is produced when a single laser is to be controlled. Multiple pulse width modulation signals are produced when multiple lasers (e.g. an RGB) are to be controlled. A laser enable logic signal 28 may also be generated and sent to the laser board drive circuit to cause it to be turned on and off, or enter a sleep mode for the purpose of conserving power.

The rechargeable battery 19, which according to some implementations is a 3.7 volt lithium battery, is electrically coupled to a battery charger 29 that receives power from a 5 volt power source through the use of a connector, such as a micro USB connector 34. As explained above, the main control board 16 may also or alternatively be powered by an external power source, which according to some implementations comprises a 9-16 volt DC external power supply. According to some implementations the external power is supplied through the micro USB connector 34.

Voltage regulators 37 and 38 are placed to step up and/or step down the voltage delivered to the microcontroller 35 and the outlet connector 27 as shown in FIG. 8. In the event a 3.7 volt lithium battery 19 is used to power the smart module, the voltage regulator 37 steps the voltage down to supply 3 volts to the microcontroller. At the same time, the voltage regulator 38 steps the voltage up to supply, for example, 9-12 volts to the output connector 27.

In the event the smart module 10 is powered by the 9-12 volt DC external power source, the voltage regulator 37 steps the voltage down to supply 3 volts to the microcontroller. At the same time, the voltage regulator 38 may adjust the voltage up or down to supply the output connector 27 with a voltage of between, for example, 9-12 volts.

The microcontroller 35 communicates with a sensor or block of sensors 36 that are located on or off the main control board. The one or more sensors may comprise, for example, one or more of a gyroscope, pressure sensor, light sensor, microphone, accelerometer, altimeter, humidity sensor, temperature sensor, etc. The microcontroller 35 is configured to receive signals from the one or more sensors and to generate an appropriate one or more pulse width modulation signals 25 in order to produce a laser visual output that varies with the parameter(s) that are measured by the one or more sensors.

As shown in FIG. 1, the smart module 10 further includes a push button on-off switch 51 attached to the main control board 16 that is used for turning the smart module on and off. A switch cap 52 fits over the push button and is accessible from outside the smart module enclosure. The smart module may also include a light sensor 50 that is operatively coupled to the main control board 16. The light sensor may be used to regulate the intensity (i.e. brightness) of the light output from the laser 12 based on the ambient light condition. For example, in a bright environment the smart module may turn the laser off while in a dim or dark environment the smart module may activate the laser and adjust the intensity of its light output based on the dimness or darkness of the ambient environment.

According to one operating example, the light diffusing fiber 30 is located in the dashboard of an automobile with the smart module being integrated into the electrical system of the car. The main control board 16 may communicate with an accelerometer that is located on the main control board or is located elsewhere in the vehicle. According to one implementation the microcontroller 35 adjusts the pulse width modulation signal 25 to cause the intensity and/or color of light emitted by the laser 12, and subsequently diffused from the fiber 30, to change based upon the acceleration being measured by the accelerometer.

Another operating example my involve attaching the smart module 10 to a kite and integrating a light diffusing fiber 30 into the structure of the kite and/or into the string to which the kite is attached and causing the intensity and/or color of light emitted by the laser 12, and subsequently diffused from the fiber 30, to change based upon the altitude being measured by an altimeter located on the main control board 16 are located elsewhere on the kite.

According to some implementations, the main control board 16 includes an antenna 39 that is capable of receiving short-range control signals, such as a Bluetooth signals, from a remote controller. The smart module 10 may include an LED 53 that, for example, is red when the Bluetooth is disabled and green when Bluetooth is enabled. According to some implementations the remote controller is in the form of an IOS application that runs on a smart phone.

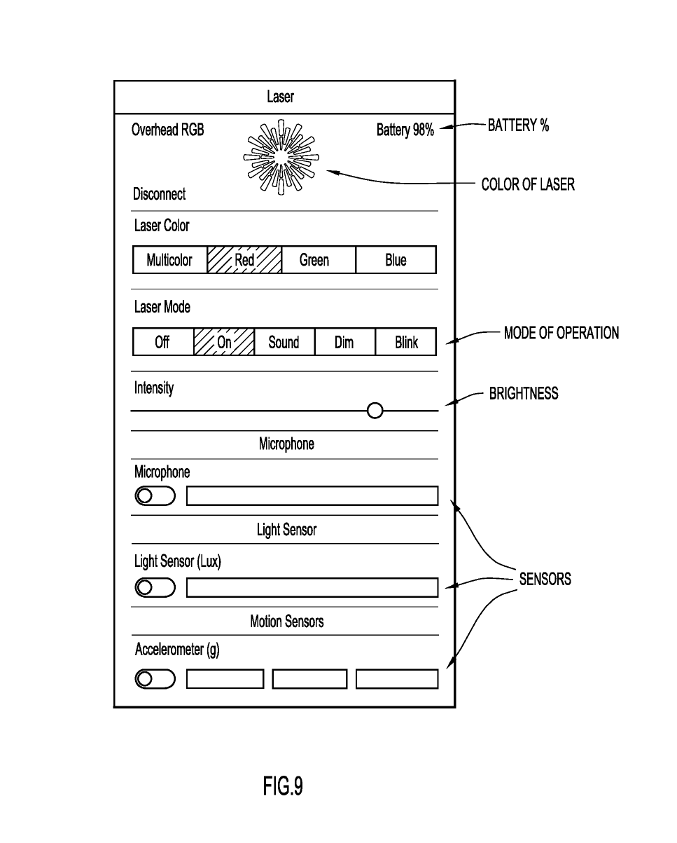

FIG. 9 is a screen shot of an exemplary touch screen display 60 through which a user may control the operation of a smart module through an IOS application running on a smartphone. In the example of FIG. 9, the display enables a monitoring of the battery status and produces a colored icon of the selected laser color. Touch screen controls are provided for the selection of the laser color (e.g. multicolor, red, green and blue) and for the selection of the laser mode of operation (e.g. off, on, sound, dim, and blink). In the sound mode a microphone in the smart module is enabled and the microcontroller 35 controls the visual output of the laser according to, for example, the beat of music. The touch screen display may also include a sliding bar for altering the brightness of the light emitted by the laser 12, as well as toggle switches for turning on and off the various sensors associated with the control module 10.

Although not shown in FIG. 8, the main control board 16 also includes memory in which instructions for operating the smart module may be stored.

To put the size of the smart module and its components into perspective, according to one implementation the external housing as shown in FIG. 6A has a length of about 2.25 inches, a width of about 1.25 inches and a height of about 0.5 inches. The smart module's compact design allows it to be easily integrated into a wide variety of products.

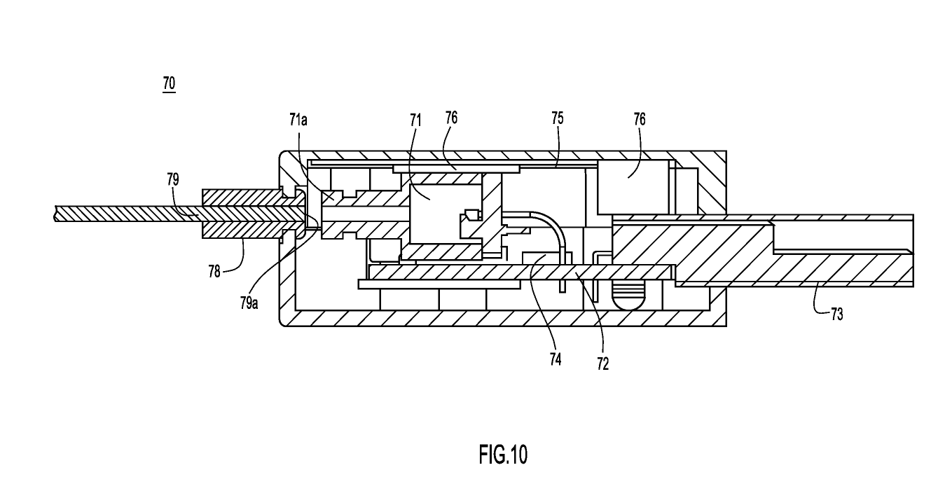

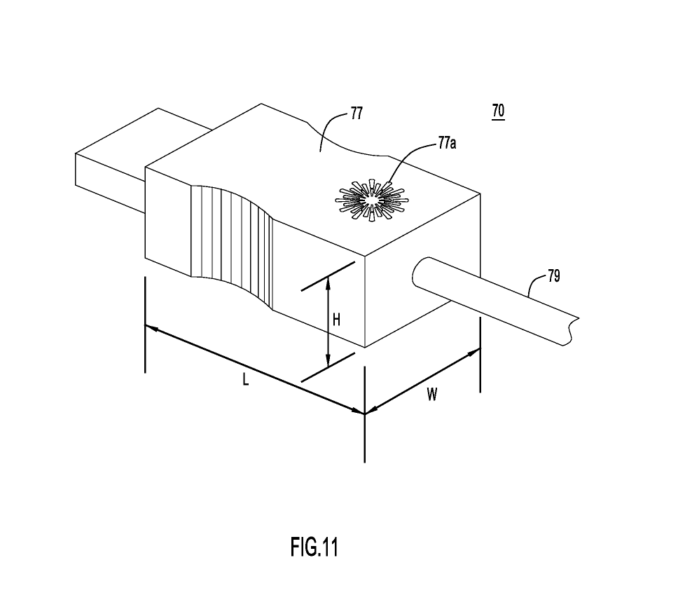

FIG. 10 illustrates a cross-sectional side view of a light generating apparatus in the form of a USB module 70. The USB module is very compact and provides a cost effective means for generating light within a light diffusing fiber 79. The USB module includes a laser 71, a laser board 72 comprising a driver circuit, and a USB connector 73. The USB connector 73 is connectable to a USB port of a computer or other device capable of providing a DC voltage power supply. The laser 71 is physically and electrically coupled to the laser board 72 and receives power from the USB connection 73 though the board.

According to some implementations the laser board 72 includes a microcontroller 74 that provides some functionality to control the visual output of the laser 71. This can be in the form of a pulse width modulation signal as explained above. In such instances, a short range antenna (not shown) is located on the laser board. The antenna is capable of receiving short-range control signals, such as a Bluetooth signals, from a remote controller. According to some implementations the remote controller is in the form of an IOS application that runs on a smart phone.

According to some implementations the light diffusing fiber 79 is connected to the distal end of the USB module via a pigtail connection 78. The proximal end 79a of the fiber is oriented facing the output 71a of the laser 71 with there being a gap existing between them.

Located at or near the top of the USB module housing is a heat spreader 75 that is thermally coupled to the laser housing and also to the USB connector 73 via the use of a thermal grease 76. This arrangement facilitates a dispersion and removal of heat produced in the laser 71 and the USB connector 73.

FIG. 11 shows a perspective view of the USB module 70. The lid of the housing 77 includes a plurality of through openings 77a through which heat generated inside the USB module may be expelled. According to one implementation, the USB module 70 has an overall length L of 1.57 inches, a width W of 0.71 inches and a height H of about 0.43 inches.

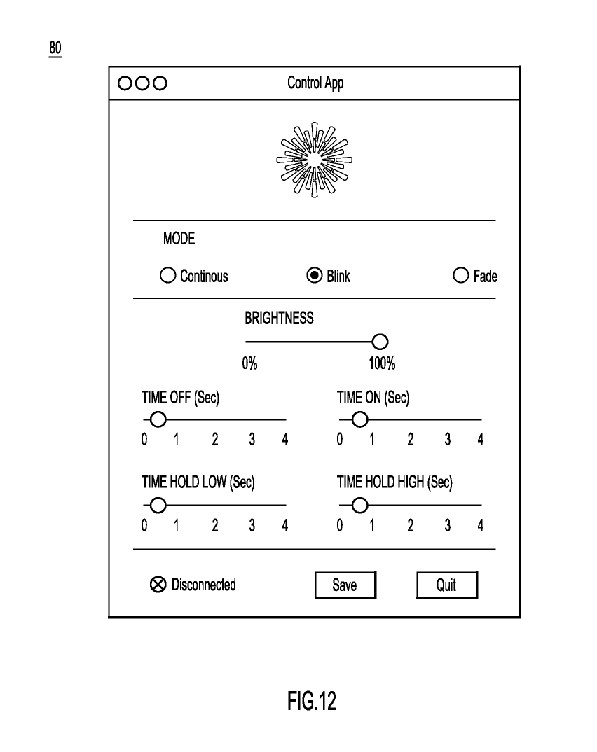

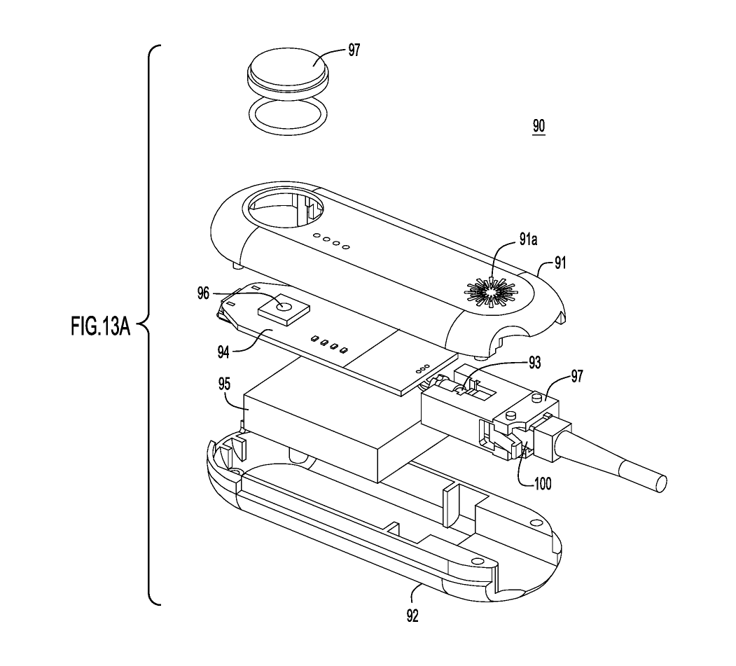

FIG. 12 is a screen shot of an exemplary touch screen display 80 through which a user may control the operation of the USB module through an IOS application running on a smartphone. In the example of FIG. 12, touch screen controls are provided for selecting a laser light output mode (e.g. continuous, fade and blank). A slide bar is also provided for adjusting the brightness of the light emitted by the laser 71. Timers are also provided for blink and fade functions where a user can select the time off and time on intervals for the light output when operating in these modes.

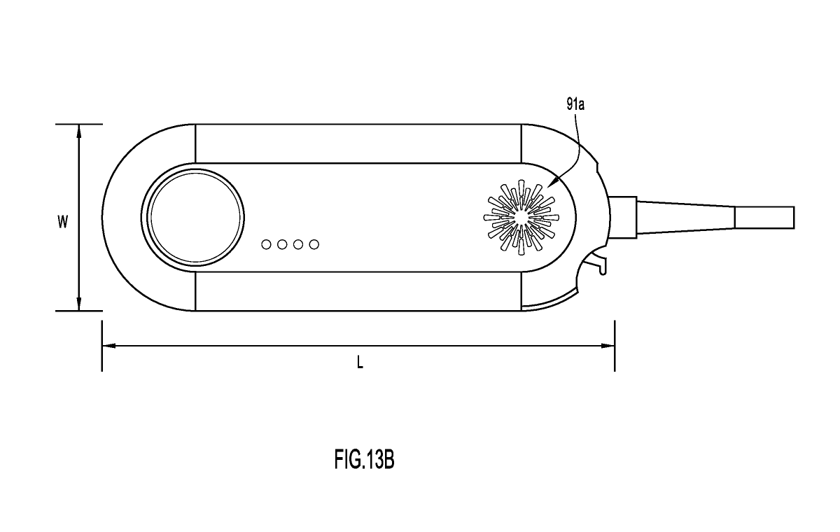

Integrating light diffusing fiber into wearable products is contemplated. For example, traffic guards, police officers and other professionals could benefit from wearables that are self-luminated to enhance safety. FIG. 13A illustrates a wearable module for generating light deliverable to a light diffusing fiber located in a wearable item, such as a jacket, vest, etc.

The wearable module 90 includes a housing in the form of a lid 91 that is connected to a base 92. Housed within the module housing is a laser 93 electrically coupled to a control board 94 that controls the voltage and current delivered to the laser. The power source for the wearable module is a battery. The printed circuit board 94 includes a microcontroller like those described above that produces a pulse width modulation signals to control the visual output of the laser 93. The control board further includes voltage and current regulating circuitry like that described above in connection with the smart module 10.

The wearable module 90 also includes a metallic receptacle 97 that functions like that described above in connection with the smart module 10. Module 90 may or may not include a heat spreader affixed to the housing lid 91. In implementations that include a heat spreader, a thermal conduction path is provided between it and the receptacle 97. As explained above, the distal end of the receptacle is configured for receiving and holding an optical connector 100 in a fixed position so that a line of sight is maintained between the laser output and the proximal end of the optical fiber that resides in a ferrule of the optical connector. The lid 91 of the housing includes a plurality of through openings 91a through which heat generated inside the wearable module may be expelled.

According to some implementations the battery is a rechargeable battery and the module 90 is provided with a micro USB port that is connected to a charger for recharging the battery. According to some implementations the module includes a battery power indicator that is viewable on a top surface of the housing lid 91.

According to one implementation the module 90 includes a push button 96 that is used to control the mode of operation. According to one implementations the modes of operation are on/off, blink and fade. As an example, a single click of the button 96 toggles the module between being on and off, a quick double click of the button 96 puts the module 90 into blink mode and a quick triple click of the button 96 puts the module 90 into fade mode. A push button cap 57 located in the housing lid 91 when depressed by a user engages the control button 96 to effectuate a change in the mode of operation of the module 90.

FIG. 13B is a top view of the wearable light generating module 90 depicted in FIG. 13A. According to one implementation, the wearable module 90 has an overall length L of ≤2.5 inches, a width W of ≤1.0 inches and a height of ≤0.5 inches. As a result of its small size, the module 90 may be worn in a pocket of a garment or be attached to the garment by the use of a clip, Velcro®, stitching, etc.

1. A light generating apparatus that is capable of being coupled to a light diffusing fiber connector that supports the proximal end of a light diffusing fiber, the apparatus comprising:
a laser having a laser housing and a focus lens through which a light beam generated by the laser is emitted,
a heat removing metallic receptacle having a first end that is thermally connected to the laser housing and a second end that is connectable to the light diffusing fiber connector, the metallic receptacle having an internal cavity that is configured to provide an unobstructed pathway for the generated light beam to pass from the focus lens of the laser and the proximal end of the light diffusing fiber when the light diffusing fiber connector is coupled to the second end of the metallic receptacle.

2. The light generating apparatus according to claim 1, further comprising a light generating apparatus housing onto which the metallic receptacle is removably attached, at least a portion of the laser and metallic receptacle residing inside the light generating apparatus housing.

3. The light generating apparatus according to claim 2, wherein the metallic receptacle is removably attached to the light generating apparatus housing without the use of an adhesive.

4. The light generating apparatus according to claim 2, wherein the metallic receptacle comprises an outer surface with one or more male parts and the light generating apparatus housing comprises one or more female parts in which the one or more male parts are housed.

5. The light generating apparatus according to claim 4, wherein the one or more male parts are press-fit into the one or more female parts.

6. The light generating apparatus according to claim 2, wherein the light generating apparatus housing comprises one or more male parts and the metallic receptacle comprises one or more female parts in which the one or more male parts are housed.

7. The light generating apparatus according to claim 6, wherein the one or more male parts are press-fit into the one or more female parts.

8. The light generating apparatus according to claim 1, wherein the metallic receptacle is made from a material selected from a group consisting of aluminum, copper, brass and zinc.

9. The light generating apparatus according to claim 1, wherein the metallic receptacle has a heat transfer coefficient of at least greater than 100 W/m·K.

10. The light generating apparatus according to claim 1, further comprising a thermal grease disposed between a surface of the metallic receptacle and a surface of the laser housing.

11. The light generating apparatus according to claim 2, further comprising a heat spreader that is supported within the light generating apparatus housing, the metallic receptacle being thermally coupled to the heat spreader.

12. The light generating apparatus according to claim 11, wherein the heat spreader has an external surface area that is greater than an external surface area of the metallic receptacle.

13. The light generating apparatus according to claim 12, further comprising a thermal grease disposed between the metallic receptacle and the heat spreader.

14. The light generating apparatus according to claim 11, wherein the light generating apparatus housing has attached first and second parts that are separable from one another, the metallic receptacle being removable attached to the first part without the use of an adhesive, the heat spreader being attached to the second part.

15. The light generating apparatus according to claim 1, further comprising:
a first printed circuit board electrically connected to an energy source,
a second printed circuit board on which the laser is mounted and electrically connected, the second printed circuit board being electrically coupled to the first printed circuit board and removably attached to the first printed circuit board, the second printed circuit board including a microcontroller.

16. The light generating apparatus according to claim 15, wherein the first printed circuit board includes a sensor that is configured to generate an electrical output signal deliverable to the microcontroller, the microcontroller being configured to generate an electrical output signal in response to the electrical output signal of the sensor, the electrical output signal of the microcontroller being indicative of a type of light to be emitted by the laser.

17. The light generating apparatus according to claim 16, wherein the second printed circuit board includes circuitry to receive and convert the electrical output signal of the microcontroller signal received from the first printed circuit board into a current that is deliverable to the laser to generate the light beam.

18. The light generating apparatus according to claim 16, wherein the first printed circuit board comprises an antenna that is capable of receiving a short-range control signal from a remote controller.

19. The light generating apparatus according to claim 18, wherein the short-range control signal is a Bluetooth signal.
